(19) United States
(12) Patent Application Publication
(10) Pub. No.: US 2011/0275196 A1
(43) Pub. Date: Nov. 10, 2011

(54) Thermal Evaporation Sources with Separate Crucible for Holding the Evaporant Material

(75) Inventor: Erten Eser, Newark, DE (US)

(73) Assignee: University of Delaware, Newark, DE (US)

(21) Appl. No.: 13/099,699

(22) Filed: May 3, 2011

Related U.S. Application Data
(60) Provisional application No. 61/330,649, filed on May 3, 2010.

(51) Int. Cl. H01L 21/20; C23C 26/00

(52) U.S. Cl. 438/478; 118/726; 118/727; 257/E21.09

(57) ABSTRACT

One aspect of the invention comprises a thermal evaporation source comprising an evaporant chamber, a heater for providing heat to the evaporation chamber; and a crucible in thermal communication with the evaporation chamber for containing a volume of evaporant. The evaporant chamber comprises a first material of construction, and the crucible comprises a second material of construction different from the first material of construction and having a lesser porosity with respect to the evaporant than the first material of construction. For example, for a copper evaporant, the evaporant chamber may comprise a sintered material, such as sintered graphite, and the crucible may comprise a pyrolytic material, such as pyrolytic graphite or pyrolytic boron nitride.

### CROSS REFERENCE TO RELATED APPLICATIONS

This application claims priority to U.S. Provisional application Ser. No. 61/330,649, entitled “THERMAL EVAPORATION SOURCES WITH SEPARATE CRUCIBLE FOR HOLDING THE EVAPORANT MATERIAL,” filed May 3, 2010, incorporated fully herein by reference.

### STATEMENT REGARDING FEDERALLY SPONSORED RESEARCH

The U.S. Government has a paid-up license in this invention and the right in limited circumstances to require the patent owner to license others on reasonable terms as provided for by the terms of Contract No. ADJ-1-30630-12, awarded by the National Renewable Energy Laboratory.

### BACKGROUND OF THE INVENTION

The high-vacuum deposition of thin films, such as Cu(InGa)Se₂, by thermal evaporation onto horizontally-oriented substrates which are spatially situated above the evaporation source (herein referred to as “vertical evaporation”) is well known, and may be useful for forming absorber layers for photovoltaic devices. Generally speaking, a vertically-evaporating thermal evaporation source comprises a substantially closed vessel containing an evaporant, typically in liquid but possibly in solid form, with at least one effusion nozzle tunneling through the upper surface of the vessel through which the elemental vapor effuses. The relative simplicity of the effusion source design is one of the significant advantages of vertical evaporation.

However, a problem with vertical (i.e., upward) evaporation is that the substrate, in particular a rigid substrate, may only be supported at its edges to avoid either shadowing the substrate surface from deposition, or marring the substrate surface by physical contacting. The restriction of supporting the substrate at its edges can for some substrates limit the substrate temperature during deposition. One particular example is glass and more particularly soda-lime glass, where using an excessively high substrate temperature (such as in the vicinity of the softening point in the case of glass) can cause warpage or breakage of the substrate. This limiting of the substrate temperature may ultimately limit the desired properties of the deposited film, such as the photovoltaic conversion efficiency of Cu(InGa)Se₂ absorber layers on soda-lime glass, as it is well known that the photovoltaic conversion efficiency of solar cells utilizing Cu(InGa)Se₂ absorber layers typically increases monotonically with substrate temperature up to a temperature of approximately 550° C.

The most basic requirements of a thermal evaporation source are a volume comprising the elemental source material, and single or plural effusion nozzles to direct the elemental vapor, generated by the melt surface, from the source interior to the substrate. In the case of a vertically-evaporating source, the effusion nozzles will ideally be within close proximity to and axially oriented normal to the melt surface. In the simplest designs, the effusion nozzles will be aimed vertically and located directly above the melt surface, as illustrated in FIG. 1. FIG. 1 shows a prior art vertical evaporating source 30 with effusion nozzles 36 passing through heat shielding 22 and situated directly above and in close proximity to the surface of evaporant material 14. The substrate to be coated is indicated at 26. The device also comprises an evaporation chamber 18 and a containment box 12.

It is desirable to minimize the external surface area of the source in order to minimize the thermal load. Further, it is desirable to minimize the aspect ratio of the source (the ratio of the major dimension to the minor dimension, upon viewing the surface of the evaporant, so as to maximize temperature uniformity within the source. A non-uniform melt temperature results in variations in vapor pressure above the melt, causing variations in effusion rate through the nozzles, ultimately contributing to non-uniform film thicknesses on the substrate. Further hindering uniform deposition is the fact that the temperature profile of the source may be expected to change as depletion of the elemental source material occurs, thereby further reducing thermal conductance along the major axis and reducing deposition uniformity. A potential remedy to the problems exhibited by the configuration in FIG. 1 is the configuration described by Baron et al (U.S. Pat. No. 4,401,052), in which a separate low-aspect-ratio melt chamber is heated to generate a vapor of the evaporant from a substantially isothermal evaporant surface. This vapor is then directed into a manifold and out through multiple effusion nozzles to the substrate. A problem with this configuration is that in the case of evaporants which require very high temperatures for sufficient vapor generation, the large surface area of this configuration may result in an unacceptably high thermal loading. Furthermore, the actual physical fabrication of this design is challenging.

Downward evaporation sources for the deposition of thin films, such as Cu(InGa)Se₂, by thermal evaporation from individual elements are known, such as for example as described in U.S. Patent application Ser. No. 12/250,172 titled “THERMAL EVAPORATION SOURCES FOR WIDE-AREA DEPOSITION,” filed Oct. 13, 2008 (“the '172 Application”), incorporated herein by reference for all that it teaches. One embodiment of a single nozzle downwards-evaporating source discussed in the '172 Application, is depicted in FIG. 2 of this application for illustration. Source 230 employs an open vessel or substantially closed chamber containing evaporant 214 volume and a vapor space 218 above it. Crucible or evaporant chamber 246 is suspended inside an expansion chamber 250 enclosed within a manifold body 240. The geometry of the source 230 is typically cylindrical, i.e., having a circular cross section as viewed from the top, but it may also have other shapes, including for example square or rectangular. The crucible is typically centered laterally. Thus, in the case where the effusion source has a circular cross section, the crucible defines an annulus with the inside walls of the manifold body.

Underneath the bottom surface of the evaporant 214 volume, a downwards-aiming nozzle 236 directs the vapor out of the manifold towards the substrate 226 (not shown), which is situated below source 230. The source 230 is typically heated from the outside surface of the manifold, in most cases by a spiral wound heating element 244 but also possibly by a serpentine heating element or a plurality of straight, vertically-oriented heating elements disposed about the circumference of the source 230. Insulation 238 typically surrounds the device. The '172 Application also refers to other designs for thermal evaporation of the same film onto horizontally oriented substrates.

For large capacity sources geared towards commercial scale manufacturing, one preferred material for evaporation sources is graphite, due to its thermal conductivity, cost, resistance to high temperature, and ease of machining. Graphite is a sintered material, however, so even if it has a small grain size, it will always present a certain level of porosity. Large quantities of molten metal, such as Cu, will typically slowly ingress into this porosity. Eventually, either the molten metal may leak through the holding chamber or, because of the thermal expansion coefficient mismatch between Cu and graphite, the chamber may crack during cool down.

### SUMMARY OF THE INVENTION

One aspect of the invention comprises a thermal evaporation source comprising an evaporant chamber, a heater for providing heat to the evaporation chamber; and a crucible in thermal communication with the evaporation chamber for containing a volume of evaporant. The evaporant chamber comprises a first material of construction, and the crucible comprises a second material of construction different from the first material of construction and having a lesser porosity with respect to the evaporant than the first material of construction. In one embodiment, the evaporant chamber may comprise a sintered material, such as sintered graphite, the crucible may comprise a pyrolytic material, such as pyrolytic graphite or pyrolytic boron nitride, and the evaporant may comprise copper.

Another aspect of the invention comprises a physical vapor deposition system comprising the thermal evaporation source as described herein, such as a system designed to fabricate solar photovoltaic modules.

Still another aspect of the invention comprises a method for performing vapor deposition using a thermal evaporation source, the method comprising providing an evaporation source as described herein, cycling through a plurality of cycles of placing evaporant in the crucible and heating the evaporation source to vaporize the evaporant, and replacing the first crucible with a second crucible identical to the first crucible, such as after wear of the first crucible.

### BRIEF DESCRIPTION OF THE DRAWINGS

The invention may be understood from the following detailed description when read in connection with the accompanying drawings. It is emphasized that, according to common practice, various features of the drawings may not be drawn to scale. On the contrary, the dimensions of the various features may be expanded or reduced for clarity. Moreover, in the drawings, common numerical references are used to represent like features. Included in the drawings are the following figures:

FIG. 1 is a cross-sectional side view of a prior art vertical evaporating source; and

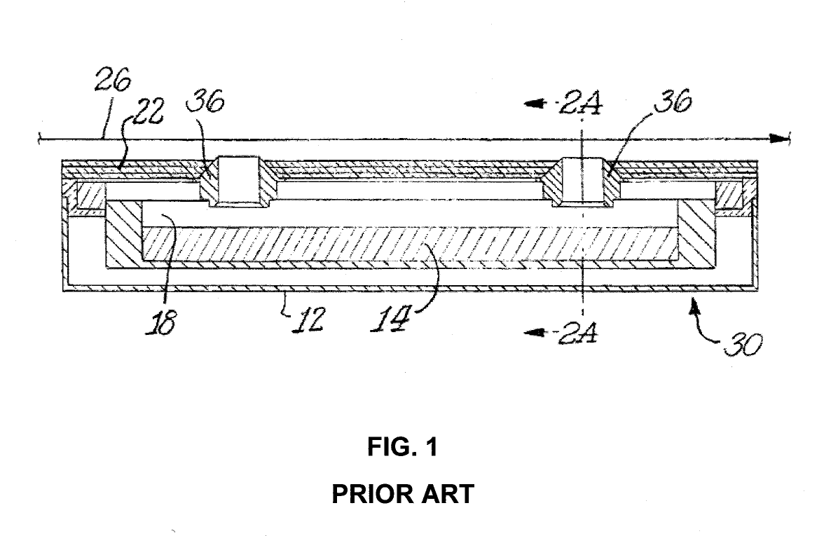

FIG. 2 is a cross-sectional side view of a prior art single nozzle downwards-evaporating source.

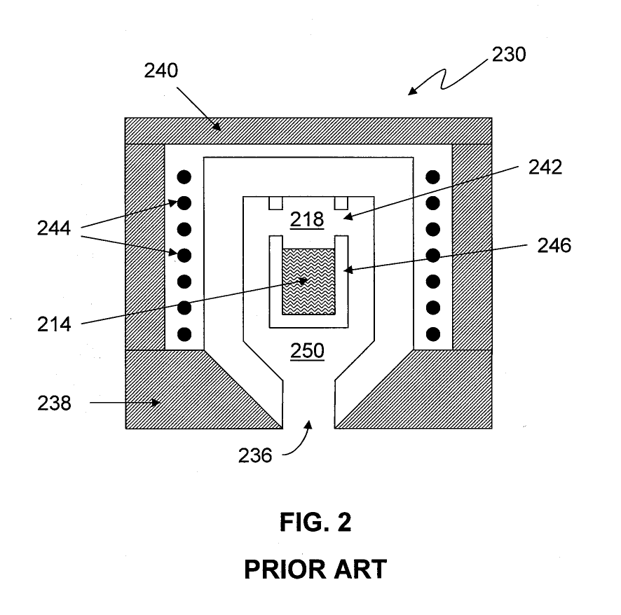

FIG. 3 is a cross-sectional schematic of an exemplary evaporant chamber with removable crucible in a downward evaporating source similar to that of FIG. 2.

### DETAILED DESCRIPTION OF THE INVENTION

Although the invention is illustrated and described herein with reference to specific embodiments, the invention is not intended to be limited to the details shown. Rather, various modifications may be made in the details within the scope and range of equivalents of the disclosure without departing from the invention.

One embodiment of the invention comprises an improvement to methods and apparatus to evaporate material over large area and for long duration, such as but not limited to that described in U.S. Patent application Ser. No. 12/250,172, previously incorporated herein by reference. One embodiment of the present invention is the introduction of a separate crucible into the evaporation chamber for containing the evaporant material, permitting the crucible to be made from a different material than the source itself. This permits construction of a crucible using materials and a design capable of withstanding the stresses associated with the large amount of evaporant, while designing the evaporation chamber with materials conducive for good heat conduction, as a result a more robust evaporation source is achieved.

One aspect of the present invention is a zero or very low porosity, high-thermal-conductivity crucible placed inside the evaporant chamber of a source to hold evaporation material. The crucible may be conformal to the evaporation chamber. Pyrolytic boron nitride or pyrolytic graphite are suitable choices for the construction of the crucible, because such materials typically do not require machining. In one embodiment of the present invention described below, pyrolytic boron nitride was used as the material for the crucible.

One aspect of the invention comprises a thermal evaporation source comprising an evaporant chamber comprising a first material of construction, a heater for providing heat to the evaporation chamber, and a crucible in thermal communication with the evaporation chamber for containing a volume of evaporant, the crucible comprising a second material of construction, wherein the second material of construction is different from and has a lesser porosity with respect to the evaporant than the first material of construction. The evaporant chamber may have a first shape comprising a bottom and one or more side walls and the crucible may have a shape that fits within and conforms to the shape of the evaporant chamber with respect to the bottom and one or more side walls.

A downwards-evaporating configuration allows the substrate to be supported across its entire width, not just at the edges, as in the case of vertical evaporation described previously. Therefore, the potential for deposition at higher substrate temperatures is one advantage, among others, in evaporating downwards from the source onto the upward-facing surface of the substrate (“downwards evaporation”), particularly when the substrate is glass. This, in turn, allows higher temperatures, since the corresponding softening of the glass is mitigated by the greater area of support.

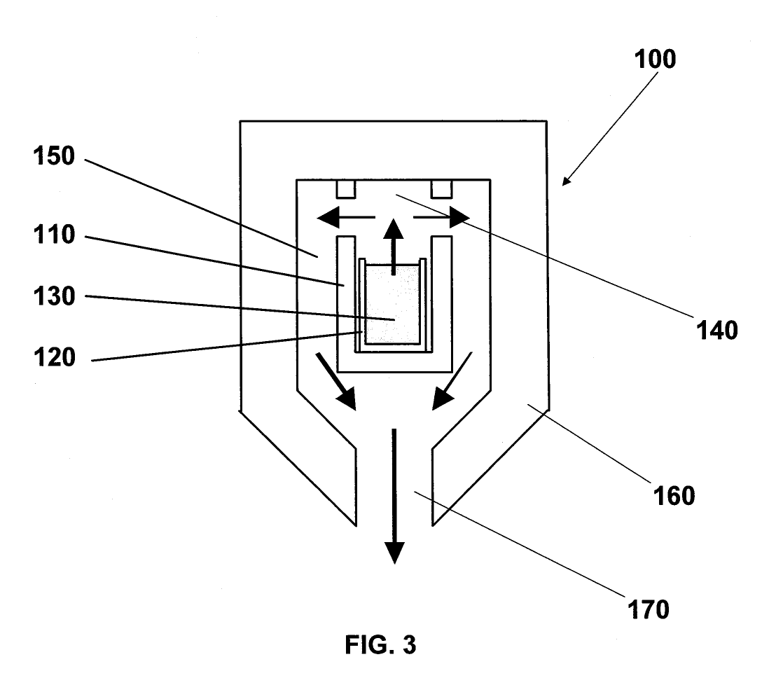

As shown in FIG. 3 of the drawings, one embodiment of a downwards-evaporating source according to the invention comprises a single nozzle source 100 having a substantially closed evaporant chamber 110 and a crucible 120. Crucible 120 separates evaporant chamber 110 from evaporant 130. It should be understood that with respect to terminology used herein, the term “evaporant chamber” 110 refers to the portion of the source that houses crucible 120. The same components could alternatively be referred to as a crucible 110 and a crucible liner 120. A volume and a vapor space 140 is directly above evaporant 130. Evaporant chamber 110 is suspended inside an expansion chamber or manifold 150 enclosed with in a manifold body 160. The geometry of the single nozzle source 100 is typically cylindrical, i.e., having a circular cross section as viewed from the top, but it may also have other shapes, including for example square or rectangular. The crucible is centered laterally. Thus, in cross section, where the effusion source has a circular cross section, the evaporant chamber 110 defines a first annulus with the inside walls of the manifold body 150, and the crucible 120 defines a second annulus with the side walls of the evaporant chamber 110.

Underneath the bottom surface of the evaporant 130 volume, a downwards-aiming nozzle 170 directs the vapor out of the manifold towards the substrate (not shown), which is situated below the single nozzle source 100. The design of the downwards-aiming nozzle 170 may be that described in U.S. Pat. Nos. 6,982,005 and 6,562,405, but other designs known in the art may also be used. The single nozzle source 100 is typically heated from the outside surface of the manifold, in most cases by a spiral wound heating element (not shown) but also possibly by a serpentine heating element or a plurality of straight, vertically-oriented heating elements disposed about the circumference of the single nozzle source 100. Insulation may also surround the device to trap heat and keep the single nozzle source 100 efficiently heated.

This particular configuration offers a number of advantages in operation. First, by using the crucible 120, the evaporant 130 is kept from contacting the evaporant chamber 110 directly. In prior art downward evaporating nozzle sources (not shown), evaporant may become contaminated when it comes in direct contact with an unlined prior art crucible or evaporant chamber. Second, in some instances, the evaporant may cause cracks in the unlined prior art crucible or evaporant chamber. Then, evaporant may leak into these cracks or enter pre-existing cracks in the unlined prior art crucible or evaporant chamber such that during the cooling process, evaporant that has seeped into the cracks may cause breakage or further cracking of the unlined prior art evaporant chamber or crucible. Using crucible 120 keeps evaporant 130 from migrating into evaporant chamber 110. By choosing a lesser porosity materials of construction for crucible 120, the potential for cracking and breakage is greatly reduced. Furthermore, to the extent that any damage may occur, it will only occur to crucible 120, which can simply be replaced with a new crucible, rather than having to re-machine a new evaporation chamber 110.

The physical dimensions of effusion source 100 can vary according to the particular needs of a given application. In some embodiments, the overall diameter of the source may be in a range of about 10-14 inches (about 25-36 cm) and the height may be in a range of about 11-16 inches (about 28-41 cm). The nozzle 170 may typically be in a range of about 2-6 cm, and more typically about 4 cm. Typical dimensions for the crucible 120 are about 14 cm outside diameter, 12 cm inside diameter, and a height sufficient to contain a pool of evaporant about 15 cm high. It will be understood to one of skill in the art from the description herein, however, that a crucible-in-source (i.e. the combination of a crucible of a first materials of construction disposed in an evaporant chamber of a second materials of construction, with materials chosen to achieve the advantages discussed herein) as discussed herein is applicable for any size vapor deposition device of a given material. This crucible-in-source will provide the same advantages described herein regardless of the size of the vapor deposition device.

Physically separating the holder for the evaporation material from the rest of the source, however, may be applied to evaporative sources of any configuration, because it separates construction and material choices of the crucible 120 from that of the evaporant chamber 110, giving flexibility for the design and construction of a robust evaporation source 100. As mentioned above, crucible 120 may comprise pyrolytic boron nitride (BN) or pyrolytic graphite. In one preferred embodiment, the crucible is formed from (and consists essentially of) bulk pyrolytic boron nitride or pyrolytic graphite materials. Additional crucible options include but are not limited to sintered graphite, sintered BN, sintered silicon carbide or any other thermally conductive refractory material coated with pyrolytic BN or with pyrolytic graphite. Thus, in one embodiment, the evaporant chamber may comprise a first materials of construction, such as a refractory material, and the crucible may comprise the same first materials of construction (or an alternate refractory material) that is coated (at least on the inner surface thereof and/or on any portion likely to come in contact with evaporant) with a second materials of construction, such as a pyrolytic material like pyrolytic boron nitride or pyrolytic graphite. In other embodiments, the removable crucible is formed entirely of bulk pyrolytic materials. Similarly, evaporant chamber 110 is typically constructed from graphite, although other materials may also be used, such as but not limited to any thermally conductive refractory material. In an alternative embodiment (not shown), evaporant chamber 110 (and, optionally, other portions of the source) may be coated with pyrolytic BN or with pyrolytic graphite, rather than the system comprising a removable crucible. Such a construction, however, is more expensive and does not enjoy the advantage of being able to simply replace a removable crucible if damage does occur after many cycles. In one embodiment, the evaporation chamber 110 may comprise a sintered material, such as but not limited to sintered graphite, and the crucible 120 may comprise a pyrolytic material, such as but not limited to pyrolytic graphite or pyrolytic boron nitride, and the evaporant may comprise copper. The source may be a downward evaporation source or any type of a source known for use in thermal evaporation systems. The resulting design provides a high capacity physical vapor deposition (PVD) source that can endure operation for a long time. Such a source is particularly suitable to the deposition of Cu(InGa)Se₂ films, from elemental sources, for the manufacture of solar photovoltaic modules based on this type of absorber material. The invention is not limited, however, to any particular type of source materials, source design, evaporant, deposition system, or end product. Accordingly, the design and construction of a source as described herein can be applied to systems for vapor deposition of any type of film in any type of industry.

In short, unlike prior art systems, exemplary PVD systems consistent with the present invention comprise a source comprising a single evaporation material held in a holder that is physically different from the rest of the source structure, with thermal communication between the holder and the source structure. The PVD source structure described herein permits large scale, uninterrupted deposition with robust operation of the source with a significantly reduced danger of the source breaking and molten evaporation material spilling. The subject source structure therefore permits long deposition runs and solves the existing problem of source breakage in conventional large capacity sources.

Another aspect of the invention comprises a physical vapor deposition system comprising a source as described herein, such as but not limited to system designed to fabricate solar photovoltaic modules.

Although the crucible is adapted for insertion within the evaporation chamber in thermal communication with the chamber, it need not be a tight fit. Relative sizing of the crucible and evaporant chamber should take into account the coefficients of thermal expansion (CTE) for the subject materials (for example, the CTE of pyrolytic BN is approximately 2.5e-6 /C and that of graphite is approximately 5.0e-6 /C) so that the fit of the crucible within the evaporant chamber at room temperature permits insertion and removal, and the fit is not subject to expansion damage at normal operating temperature and during heating from room temperature to normal operating temperature. The crucible and the evaporant chamber may be in thermal communication with one another by conduction and/or radiation. For example, the crucible bottom is typically in thermal communication with the bottom of the evaporant chamber via conduction, and the crucible walls are typically in thermal communication with the walls of the chamber via radiation. Thus, as used herein, the reference that the two are “in thermal communication with” one another is not limited only to conductive communication, nor is it limited to direct contact between the crucible and the evaporant chamber (i.e. one or more materials may be juxtaposed between the evaporant chamber and the crucible to permit heat conduction from one to the other). Accordingly, there is no need for the crucible to be a tight fit within the evaporant chamber, either at room temperature or at normal operating temperature.

### EXAMPLE

In one embodiment of the present invention, laboratory experiments were conducted with a downward-facing evaporation chamber similar to the one described above. The experimental evaporation chamber included a crucible made of pyrolytic boron nitride. The crucible contained 10 pounds of copper. Using the method and configuration described above, the copper was evaporated without damaging the source and without contamination of the copper by the material of the main source. Prior experiments conducted without the pyrolytic boron nitride crucible caused the copper to become contaminated with the graphite from the evaporant chamber. Furthermore, the pyrolytic boron nitride crucible prevented molten copper from seeping into the graphite and prevented breakage of the graphite. The pyrolytic boron nitride provides a proper casement for the molten copper and prevents it from contacting the graphite. As mentioned, this experiment was replicated with 10 pounds of copper, which would be equivalent to amounts that would be used in commercial aspects of the application.

While preferred embodiments of the invention have been shown and described herein, it will be understood that such embodiments are provided by way of example only. Numerous variations, changes and substitutions will occur to those skilled in the art without departing from the spirit of the invention. Accordingly, it is intended that the appended claims cover all such variations as fall within the spirit and scope of the invention.

What is claimed:

1. A thermal evaporation source comprising:
an evaporant chamber comprising a first material of construction;
a heater for providing heat to the evaporation chamber;
a crucible in thermal communication with the evaporation chamber for containing a volume of evaporant, the crucible comprising a second material of construction;
wherein the second material of construction is different from and has a lesser porosity with respect to the evaporant than the first material of construction.

2. The source of claim 1, wherein the second material of construction has a zero porosity with respect to the evaporant.

3. The source of claim 1, wherein the evaporant chamber has a first shape comprising a bottom and one or more side walls and the crucible has a shape that fits within and conforms to the shape of the evaporant chamber with respect to said bottom and one or more side walls.

4. The source of claim 3, wherein the crucible and the evaporant chamber each have a circular cross section and the crucible defines a first annulus relative to the side walls of the evaporant chamber in cross section.

5. The source of claim 4, wherein the evaporant chamber is housed within a manifold having inside walls defining a circular cross section, and the evaporant chamber defines a second annulus with the inside walls of the manifold.

6. The source of claim 1, wherein the evaporant chamber comprises a sintered material and the crucible comprises a pyrolytic material.

7. The source of claim 1, wherein the evaporant chamber comprises sintered graphite and the evaporation chamber comprises pyrolytic graphite or pyrolytic boron nitride.

8. The source of claim 7, wherein the evaporant comprises copper.

9. The source of claim 1, wherein the evaporant comprises copper.

10. The source of claim 1, wherein the source is a downward evaporation source.

11. The source of claim 1, wherein the thermal communication with the evaporant chamber comprises conduction.

12. The source of claim 1, wherein the thermal communication with the evaporant chamber comprises radiation.

13. The source of claim 1, wherein the thermal communication with the evaporant chamber comprises a combination of conduction and radiation.

14. The source of claim 1, wherein the crucible is removable from the evaporant chamber.

15. The source of claim 14, wherein the crucible comprises the first material of construction coated with the second material of construction on at least an inner surface thereof.

16. The source of claim 1, wherein the crucible comprises a non-removable coating on the evaporant chamber.

17. A physical vapor deposition system comprising the source of claim 1.

18. The physical vapor deposition system of claim 17, comprising a system designed to fabricate solar photovoltaic modules.

19. A method for performing vapor deposition using a thermal evaporation source, the method comprising:
(a) providing an evaporation source comprising an evaporant chamber comprising a first material of construction; a heater; a first crucible for holding evaporant in thermal communication with the evaporation chamber and comprising a second material of construction different from the first material of construction and having a lesser porosity with respect to the evaporant than the first material of construction;
(b) placing evaporant in the crucible;
(c) heating the evaporation source with the heater to vaporize the evaporant;
(d) repeating steps (b) and (c) for a plurality of cycles;
(e) replacing the first crucible with a second crucible identical to the first crucible.
